(19) United States
(12) Patent Application Publication
(10) Pub. No.: US 2008/0157286 A1
(43) Pub. Date: Jul. 3, 2008

(54) Semiconductor device having a indicator indicating cleavage direction

(75) Inventor: Takayuki Iwaki, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/003,168

(22) Filed: Dec. 20, 2007

(30) Foreign Application Priority Data
Dec. 27, 2006 (JP) 2006-351483

(51) Int. Cl. H01L 23/544

(52) U.S. Cl. 257/620; 257/E23.179

(57) ABSTRACT

An indicator that denotes the cleavage direction is arranged along with an integrated circuit of a semiconductor chip. This indicator makes it possible to cut the semiconductor chip along the cleavage direction even if the integrated circuit is arranged not to be in the cleavage direction.

### BACKGROUND OF THE INVENTION

1. Field of the Invention

The present invention relates to a semiconductor device of a structure obtained by dicing a semiconductor wafer on which integrated circuits are formed.

2. Description of Related Art

A semiconductor device (semiconductor chip) is fabricated by forming an integrated circuit on a semiconductor wafer by a semiconductor process, and then dividing (dicing) this semiconductor wafer with scribelines.

The integrated circuit of semiconductor device includes a plurality of semiconductor circuits and a plurality of interconnect patterns. The integrated circuit of the semiconductor device is generally formed on a rectangular circuit region. In the present specification, such formation is termed “circuit directions” of the integrated circuit.

The plurality of semiconductor circuits of the integrated circuit are generally formed on a rectangular device region, most of which are arranged in directions parallel to the four sides of the rectangular device region. In the present specification, these directions are termed “device directions” of the semiconductor circuit.

Also, the interconnect patterns of the integrated circuit are generally formed in line-shape, and most of the interconnect patterns are also formed in directions parallel to the above mentioned device directions. In the present specification, these directions are termed “pattern directions” of the interconnect patterns.

Semiconductor wafers are made of silicon crystal. Accordingly, they have at least one cleavage direction. In conventional semiconductor devices, the above mentioned circuit direction, device direction, and pattern direction have all matched the cleavage direction of a semiconductor substrate of diced semiconductor wafers.

Furthermore, line directions of the scribelines and the cleavage direction of the semiconductor wafer are matched as well. For this reason, in a semiconductor wafer used in fabrication of semiconductor device, the directions of notches and orientation flat match the cleavage direction.

Alternatively, semiconductor devices are recently being fabricated in a state in which the above mentioned circuit direction, device direction, interconnect direction, line direction, formation direction of notches and orientation flat, and the like, do not match the cleavage direction of the semiconductor wafer in order to improve semiconductor device performance.

Japanese Patent Laid-Open No. 61-214421 discloses a technique that forms a first orientation flat which has had its direction matched with the cleavage direction, and a second orientation flat that does not match the cleavage direction with its direction, in semiconductor wafers in which the line direction of the scribelines of the semiconductor device and the cleavage direction do not match as mentioned above.

In a case in which a defect has occurred in a semiconductor device (semiconductor chip) formed by dicing a semiconductor wafer with scribelines, the semiconductor device (semiconductor chip) may be cut for analysis of the cross section. In such a case, analysis of the cross section of the semiconductor device is executed by cleaving at a cleavage face of the semiconductor device.

With the semiconductor wafer of the above mentioned Patent Document, it is possible, according to the second orientation flat, to easily fabricate the semiconductor wafer in a state in which the direction of the semiconductor circuit does not match the cleavage direction of the semiconductor wafer. In such a case as well, it is possible, according to the first orientation flat, to easily confirm the cleavage direction of the semiconductor wafer.

However, in the state of the semiconductor device, in which a semiconductor wafer fabricated with semiconductor circuit has been diced, it is not possible to use the second orientation flat, and for this reason it is not possible to confirm with ease the cleavage direction of the semiconductor substrate composed of the diced semiconductor wafer.

Simply stated, it is difficult to correctly recognize the cleavage direction when executing defect analysis with a semiconductor device in which the line directions of the scribelines do not match the cleavage direction of the semiconductor wafer.

Also, even if the semiconductor device is one in which the line directions of the scribelines do match the cleavage direction of the semiconductor wafer, it is necessary to confirm the relationship between the line directions of the scribelines and the cleavage direction for each of semiconductor devices to be analyzed, since, as mentioned above, some of the semiconductor devices can be fabricated in a state in which these directions do not match. For this reason, cross section analysis is impeded regardless of which of case is in question.

It is possible to execute cross section exposure by using techniques such as FIB (Focused Ion-Beam) Analysis for example, rather than using the cleavage direction. However, some of the problems with FIB Analysis is that the area of inspection is extremely small, the duration of the inspection is long, and the equipment is expensive.

### SUMMARY OF THE INVENTION

A semiconductor device includes a structure obtained by dicing a semiconductor wafer on which integrated circuits including a plurality of semiconductor circuits and a plurality of interconnect patterns are formed by a semiconductor process, with a scribeline with respect to each of said integrated circuits. The semiconductor includes an indicator which denotes a cleavage direction of the semiconductor device.

Therefore, it is possible to confirm with ease the cleavage direction according to the indicator. Accordingly, it is possible to execute acts such as cutting the semiconductor device in the cleavage direction according to this indicator.

It is noted that the integrated circuit is formed by integrating a plurality of semiconductor circuits and a plurality of interconnect patterns in prescribed circuit regions. In a case in which those circuit regions are formed in a rectangular shape, the directions of the four sides of the rectangle are the circuit directions of the integrated circuit.

Also, when a majority of the semiconductor circuit forming the integrated circuit is formed in a rectangular shape for example, the device directions of the semiconductor circuit may be the directions of the four sides of the rectangle. Furthermore, when a majority of the linear interconnect patterns formed in the integrated circuit are formed in a prescribed direction, the pattern direction of the interconnect pattern may be the linear direction thereof.

The line direction of the scribelines may be the linear direction of the scribelines. Note that in a typical semiconductor device the above mentioned device direction, circuit direction pattern direction and line direction all match.

With the features, it is possible to confirm with ease the cleavage direction according to the indicator. Accordingly, it is possible to execute acts such as cutting the semiconductor device in the cleavage direction in correspondence with the indicator and conducting analysis of the cross section.

### BRIEF DESCRIPTION OF THE DRAWINGS

The above and other exemplary aspects, advantages and features of the present invention will be more apparent from the following description of certain exemplary embodiments taken in conjunction with the accompanying drawings, in which:

FIG. 1 is a schematic top view showing the external appearance of a semiconductor device of an embodiment of the present invention;

FIG. 2 is a schematic top view showing the external appearance of a semiconductor wafer;

FIG. 3 is a schematic view showing a first process step in an inspection method of the semiconductor device;

FIG. 4 is a schematic view showing a second process step in the inspection method of the semiconductor device;

FIG. 5 is a schematic view showing a third process step in the inspection method of the semiconductor device;

FIG. 6 is a schematic top view showing the external appearance of a semiconductor device of a modification;

FIG. 7 is a schematic view showing an inspection method of a semiconductor device of another modification;

FIG. 8 is a schematic top view showing an indicator of a semiconductor device of another modification; and

FIG. 9 is a schematic top view showing an indicator of a semiconductor device of another modification.

### DETAILED DESCRIPTION OF THE EXEMPLARY EMBODIMENT

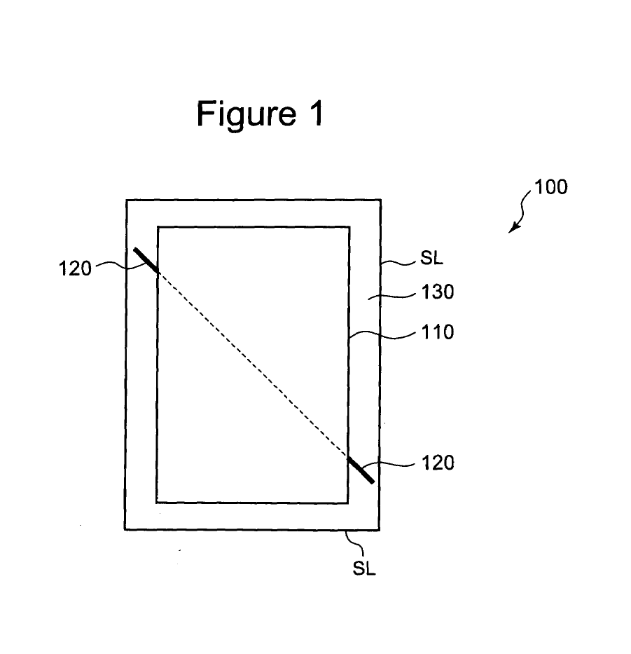

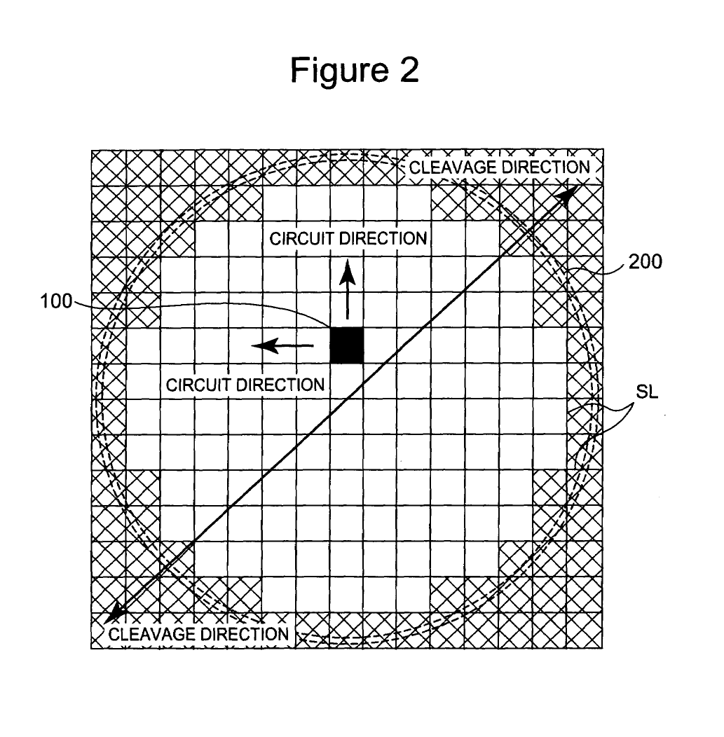

FIGS. 1 to 5 shows an embodiment of the present invention. As shown in FIGS. 1 and 2, a semiconductor device 100 of the present embodiment, is formed with a structure obtained by dicing a semiconductor wafer 200 of integrated circuit 110 formed by a semiconductor process, with a scribeline SL. Therefore, the semiconductor device 100 of the present invention includes a bare chip.

The semiconductor wafer 200 composed of semiconductor materials Such as silicon and GaAs is crystalline in structure and therefore includes at least one cleavage direction. For this reason, in the semiconductor device 100 of the present embodiment, cut out from the semiconductor wafer 200, there is at least one cleavage direction in a semiconductor substrate 130.

A semiconductor circuit 110 includes a plurality of semiconductor circuits and a plurality of interconnect patterns that form and connect these semiconductor circuits together (not shown). The semiconductor circuits are formed to be rectangular in shape and a majority of them are arranged in directions parallel to the four sides of the rectangle. Also, the semiconductor circuits referred to here are circuit blocks and macros constituting the semiconductor device.

The integrated circuit 110 is formed of a plurality of semiconductor circuits. In the present embodiment, the integrated circuit 110 constituted in this manner also exhibits a rectangular shape. As stated before, the circuit direction of the integrated circuit 110 is the direction parallel to the four sides of the rectangular semiconductor circuit constituting the integrated circuit 110.

Also, in the present embodiment, the line directions of the scribeline SL, and the pattern directions of the plurality of interconnect patterns that form and connect the semiconductor circuits, are both made in a directions parallel to the four sides of the semiconductor circuit.

Here, the circuit directions of the semiconductor circuit, the pattern directions of the interconnect pattern, and the line directions of the scribeline SL, are set not to match (e.g. not to align with) the cleavage direction. However, as is shown in FIG. 1, there is formed in the semiconductor device 100 of the present embodiment an indicator 120 that denotes the cleavage direction.

More specifically, the interconnect pattern of the integrated circuit 110 is formed of metals such as aluminum, copper, tungsten, and titanium nitride, and of polysilicon, metallic silicide, and the like.

Interconnect patterns formed of metallic material serve, for example, as signal lines and power supply lines either within or outside of the semiconductor circuit. Interconnect patterns formed of polysilicon, metallic silicide, and the like, serve, for example, as the interconnect pattern of gate leads of transistors constituting the semiconductor circuit. Also, the indicator 120 is formed by a semiconductor process along with the interconnect patterns of the integrated circuit 110.

The semiconductor device 100 of the present embodiment includes a rectangular semiconductor substrate 130 formed by the semiconductor wafer 200, which has been diced with the scribeline SL. The integrated circuit 110 is formed on a rectangular region on the surface (circuit face) of the semiconductor substrate 130.

The indicator 120 is formed on the outside of the integrated circuit 110. Accordingly, the indicator 120 includes a dummy interconnect pattern that does not function as a part of the integrated circuit 110. This indicator 120 is formed as a pair separated linearly parallel to the cleavage direction. Furthermore, each member of this pair is formed in a linear shape parallel to the cleavage direction.

Furthermore, the indicator 120 of the kind mentioned above is formed at a size that enables viewing with an optical microscope when, for example, observation with an optical microscope (not shown) is necessary for cross section analysis of the semiconductor device 100.

Also, the indicator 120 is formed on a layer that enables viewing with an optical microscope for analysis of cross section, for example, the top-most layer of the integrated circuit 110, which is multi-layered. Note that the size of the indicator 120 may be an arbitrary size. In a case in which precision is not a matter of concern, the size of the indicator 120 may be large enough to enable viewing with the naked eye.

First, a fabrication method for the semiconductor device 100 of the present embodiment will be simply described below with respect to the constitution as stated above. As is shown in FIG. 2, a plurality of integrated circuits 110 that will each become the semiconductor device 100 are formed on the semiconductor wafer 200 by a semiconductor process.

In this case, the plurality of integrated circuits 110 are formed in a rectangular shape arranged to front, back, left, and right. A plurality of semiconductor devices 100 are formed by this integrated circuit 110 being diced with the scribeline SL formed on the semiconductor wafer 200 on the front, back, left, and right.

However, in the semiconductor device 100 of the present embodiment, though the circuit direction of the semiconductor circuit, the pattern direction of the interconnect pattern, and the line direction of the scribeline SL all match each other, these directions do not match the cleavage direction.

Thus, when forming the integrated circuit 110 on the semiconductor wafer 200 as mentioned above by a semiconductor process, the indicator 120 that denotes the cleavage direction is also formed in the semiconductor process as is shown in FIG. 1.

Next, a specific example of the inspection method of the semiconductor device 100 of the present embodiment will be described below. For example, in a case in which a deficiency has occurred in a fabricated semiconductor device 100, the semiconductor device 100 will be loaded into an optical microscope, and given a scratch line at an analysis area A.

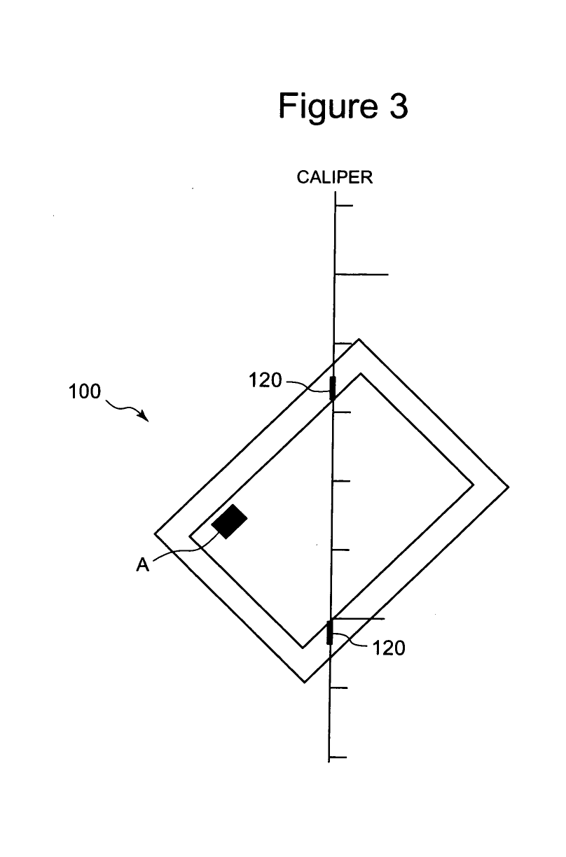

In such a case, as stated above it is possible to view the indicator 120 of the semiconductor device 100 with an optical microscope. Then, as shown in FIG. 3, a caliper line on the optical microscope is set to meet the indicator 120 of the semiconductor device 100.

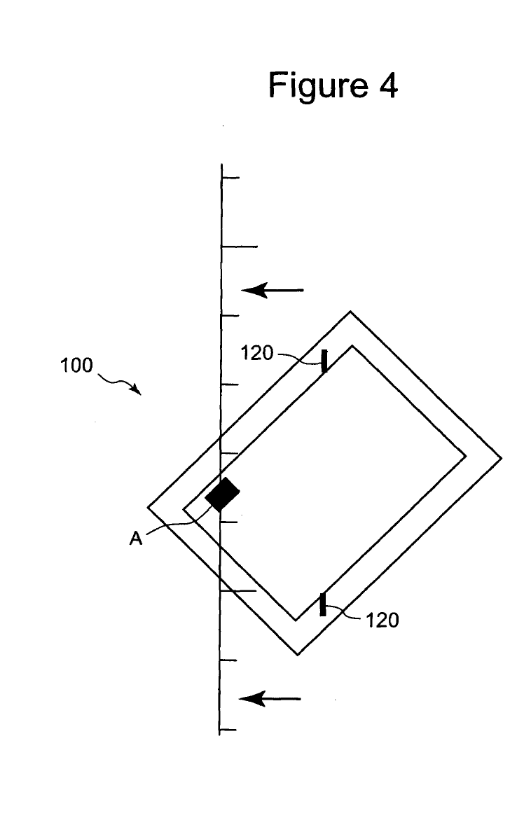

Next, as shown in FIG. 4, the caliper line in a parallel manner is moved to a desired location on the analysis area A of the semiconductor device 100. Then the scratch line is applied to the semiconductor device 100 in alignment with this caliper line.

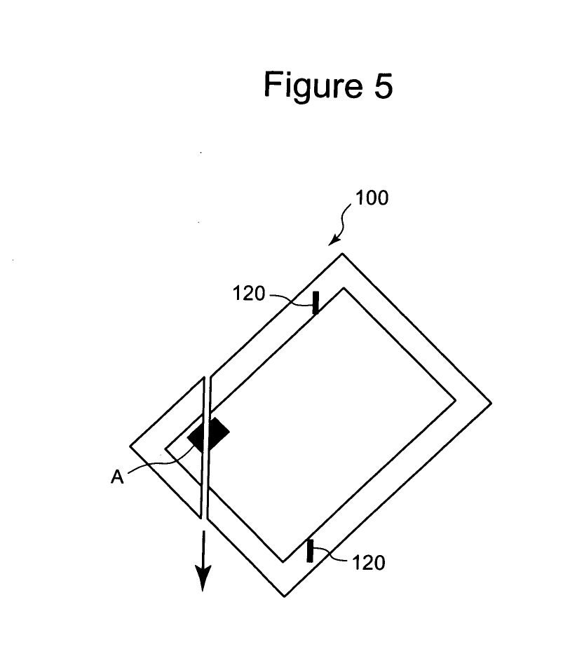

Next, as shown in FIG. 5, the semiconductor device 100 is cut along this scratch line. When this is performed, the analysis area A will be cut at a cross section parallel to the cleavage direction of the semiconductor wafer 200. Because of this, it is possible to execute desirable cross section analysis of the analysis area A of the semiconductor device 100.

With the semiconductor device 100 of the present embodiment, it is possible, according to the indicator 120, to confirm with ease the cleavage direction of the semiconductor wafer 200, with the cleavage direction not matching the circuit direction of the semiconductor circuit, the pattern direction of the interconnect pattern, and the line direction of the scribeline SL, as is mentioned above. For this reason, it is possible to execute acts such as cutting of the semiconductor device 100 in the cleavage direction in correspondence to the indicator 120 and analysis of the cross section thereof.

In particular, the indicator 120 is formed along with the interconnect pattern of the integrated circuit 110. Accordingly, it is not necessary to add a fabrication process step for the sole purpose of forming the indicator 120. Therefore, the productivity of the semiconductor device 100 is not hindered by the indicator 120.

Also, the indicator 120 is made of a dummy interconnect pattern that does not function as a part of the integrated circuit 110. Accordingly, the functionality of the integrated circuit 110 is never hindered by the indicator 120.

Furthermore, the indicator 120 is formed outside of the integrated circuit 110. Because of this, the occupancy space of the integrated circuit 110 is never cut for the purpose of forming the indicator 120. Also, it is possible to locate the indicator 120 with ease.

The indicator 120 is formed in a linear shape parallel to the cleavage direction. Thus, it is possible to confirm with ease the cleavage direction of the semiconductor substrate 130. In particular, the indicator 120 is formed as a pair in a linear shape parallel to the cleavage direction. Accordingly, it is possible to confirm the cleavage direction of the semiconductor substrate 130 with good precision.

Note that the present invention is not limited to the present embodiment and various embodiments can be made without departing from the main gist of the present invention. For example, the above embodiment illustrates an example of the indicator 120 being formed in correspondence to a cleavage direction of the semiconductor wafer 200.

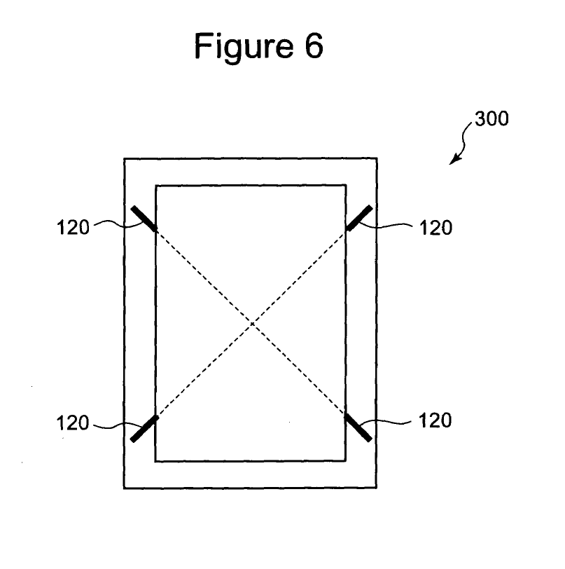

However, there are two cleavage directions in the semiconductor wafer 200. Accordingly, indicators 120 may be formed on a semiconductor device 300 in correspondence to a plurality of cleavage directions, as shown in FIG. 6.

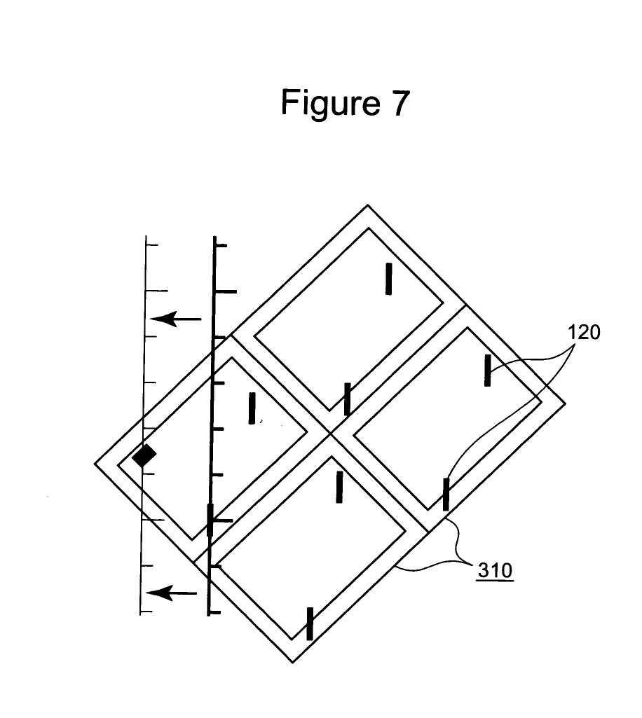

Also, the above described embodiment illustrates an example of the indicator 120 being formed outside of the integrated circuit 110. However, the indicator 120 may be formed spanning from outside of the integrated circuit 110 to inside of it, and the entire portion of the indicator 120 may be formed inside of the integrated circuit 110 as shown in a semiconductor device 310 illustrated in FIG. 7.

Furthermore, the above described embodiment illustrates an example of the indicator 120 situated outside of the integrated circuit 110 being made of a dummy interconnect pattern that does not function as a part of the integrated circuit 110. However, in the case where the entire portion of the indicator 120 is situated inside of the integrated circuit 110 as shown in a semiconductor device 310 illustrated in FIG. 7, the indicator 120 may be a portion of the interconnect pattern that functions as the integrated circuit 110.

Also, the above described embodiment illustrates an example in which the indicator 120 is made of a pair separated linearly parallel to the cleavage direction and each member of the pair is formed in a linear shape parallel to the cleavage direction. However, in the case of forming the indicator 120 as a pair separated linearly parallel to the cleavage direction, each member of the pair may be point-like (not shown). Alternatively, in the case of forming the indicator 120 in a linear shape parallel to the cleavage direction, the indicator 120 may be a single independent line, as shown in the semiconductor device 310 illustrated in FIG. 7.

Furthermore, the above described embodiment illustrates an example in which inspection is executed to a semiconductor device 100 in a state of having been diced to a single die. However, inspection may be executed thereto in a state of a colony composed of a plurality of semiconductor devices 310, as is shown in FIG. 7.

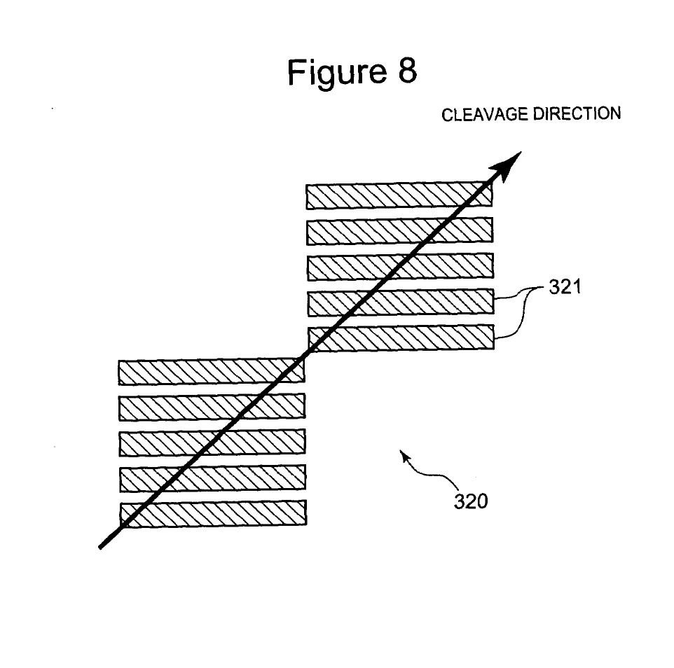

Furthermore, the above described embodiment illustrates an example in which the indicator 120 is constituted of a linear shaped interconnect pattern. However, such an indicator may be an aggregate of a plurality of interconnect patterns. For example, when a rectangular aggregate of parallel-aligned interconnect patterns 321 of prescribed length is formed as shown in FIG. 8, a diagonal line of the rectangular aggregate can function as an indicator 320.

In this case, it is possible to form each of the interconnect patterns 321 in the pattern direction in the same manner as conducted for a conventional interconnect pattern. Accordingly, it is not necessary to form a interconnect pattern of a special direction for the sole purpose of forming the indicator 320.

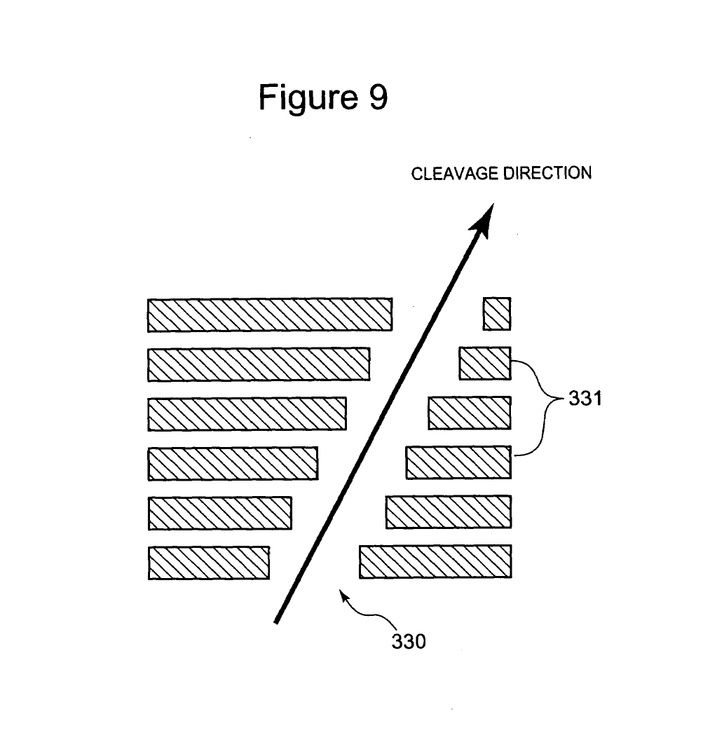

Also, it is possible to form an indicator from a gap portion formed on an aggregate of a plurality of interconnect patterns. For example, when a rectangular aggregate of parallel-aligned interconnect patterns 331 of prescribed length is formed as shown in FIG. 9, a linear shaped gap portion on this aggregate may be an indicator 330.

In this case as well, it is possible to form each of the interconnect patterns 331 in the pattern direction in the same manner as conducted for a conventional interconnect pattern. Accordingly, it is not necessary to form an interconnect pattern of a special direction for the sole purpose of forming the indicator 330.

Furthermore, the above described embodiment illustrates an example in which the indicator 120 is formed on the topmost layer of the multi-layer structured integrated circuit 110. However, the indicator 120 may also be formed on a layer below the topmost layer, or the indicators 120 may be formed on a plurality of layers, as long as the indicator 120 is in a state in which it can be confirmed during cross section analysis.

Also, in the above described embodiment an example is indicated in which the indicator 120 is formed along with a interconnect pattern of metallic constitution. It is however acceptable to form the indicator 120 of any kind of structure as long as it is one that is able to be confirmed through an optical microscope or the naked eye.

The indicator 120 may be formed along with the semiconductor layers forming the integrated circuit 110, or may be defined with ridges and recesses of the interconnect pattern or insulation film or the both. It is also possible to form holes and pits in the semiconductor substrate 130 and then fill in those holes and pits with silicon oxide film to form the indicator 120.

Furthermore, although it was described in the above embodiment that the line direction of the scribeline SL, and the pattern directions of the plurality of interconnect patterns that form and connect the semiconductor circuits are both created in directions (the circuit directions of the semiconductor circuit) parallel to the four sides of the semiconductor circuit, it is also possible to establish the indicator 120 of the present invention in a semiconductor device (semiconductor chip) in which those directions are different from each other.

Although the case described was one in which the line direction of the scribeline SL, the pattern direction of the plurality of interconnect patterns forming and connecting the semiconductor circuits and the circuit direction of the semiconductor circuit are different from the cleavage direction of the semiconductor substrate 130 of the semiconductor device 100, it is also possible to form the indicator 120 of the present invention on a semiconductor device (semiconductor chip) in which at least one of the line direction, the pattern direction and the circuit direction matches the cleavage direction of the semiconductor substrate 130 of the semiconductor device 100.

Similarly, in the case of semiconductor devices (semiconductor chips) in which conventional line directions, pattern directions and circuit directions all match the cleavage direction of the semiconductor substrate 130 of the semiconductor device 100, the indicator 120 can also be formed therein thereby eliminating the need to confirm the relationship between the line direction of the scribeline or the like and the cleavage direction for each semiconductor device to be analyzed.

The indicator 120 may be formed not only on the front face of the semiconductor substrate 130, having thereon the integrated circuit 110 of the semiconductor device 100, but also on a rear face of the semiconductor substrate 130 (the opposite face to the circuit face).

The indicator 120 may be formed on at least one face or be formed on both faces. In the case of a flip-chip type semiconductor device, this is because only formation of the indicator 120 on the rear face (the opposite face of the circuit face) of the semiconductor substrate 130 can provide excellent recognizability.

Furthermore, of course the above described embodiments and modifications can be combined within a scope in which their content remains consistent.

The semiconductor device (semiconductor chip) of the present invention includes the indicator 120 that denotes the cleavage direction of the semiconductor substrate of the semiconductor device (semiconductor chip) pertaining to each semiconductor device (semiconductor chip) even when each semiconductor device (semiconductor chip) is diced and cut out from the semiconductor wafer.

Therefore, it allows the cleavage direction of the semiconductor substrate 130 constituting the semiconductor device (semiconductor chip) to be recognized, and the indicator 120 can be used to easily cleave and attain a cross section of the semiconductor device in cross section analysis of the semiconductor device or the like.

The present invention has been described based on the above examples, but the present invention is not limited only to the above examples, and includes various kinds of alterations and modifications that could be achieved by a person skilled in the art within the scope of the invention of each of claims of this application as a matter of course.

Further, it is noted that, Applicant's intent is to encompass equivalents of all claim elements, even if amended later during prosecution

What is claimed is:

1. A semiconductor device, comprising:
an integrated circuit including a semiconductor circuit and an interconnect pattern, said integrated circuit being defined by a scribeline; and
an indicator, adjacent to said integrated circuit, which denotes a cleavage direction of said semiconductor device.

2. The semiconductor device according to claim 1, wherein said indicator is placed on at least one of a circuit face of said semiconductor device and a rear face of said circuit face of said semiconductor device.

3. The semiconductor device according to claim 1, wherein a line direction of said scribeline differs from said cleavage direction.

4. The semiconductor device according to claim 1, wherein a pattern direction of said interconnect pattern differs from said cleavage direction.

5. The semiconductor device according to claim 1, wherein said semiconductor circuit includes a rectangular shape having four sides, a direction of said four sides differing from said cleavage direction.

6. The semiconductor device according to claim 1, wherein said indicator is arranged along with said integrated circuit.

7. The semiconductor device according to claim 1, wherein said indicator is arranged along with said interconnect pattern.

8. The semiconductor device according to claim 1, wherein said indicator comprises a portion of said interconnect pattern.

9. The semiconductor device according to claim 1, wherein said indicator comprises a dummy interconnection pattern that functions as other than a portion of said integrated circuit.

10. The semiconductor device according to claim 1, wherein said indicator comprises an aggregate of a plurality of interconnect patterns.

11. The semiconductor device according to claim 1, wherein said indicator comprises a gap portion formed on an aggregate of a plurality of said interconnect patterns.

12. The semiconductor device according to claim 1, wherein said indicator is located outside of said integrated circuit.

13. The semiconductor device according to claim 1, wherein said indicator is arranged in a linear shape parallel to said cleavage direction.

14. The semiconductor device according to claim 1, wherein said indicator is arranged in a separated pair in a linear shape parallel to said cleavage direction.

15. The semiconductor device according to claim 1, wherein said indicator is arranged on a top-most interconnect layer of said semiconductor device.

16. The semiconductor device according to claim 1, wherein said indicator comprises a structure of a insulating substance filled into holes or pits formed in said semiconductor device.

17. A semiconductor chip, comprising:
a semiconductor substrate, which has an edge having a direction different from a cleavage direction of said semiconductor substrate; and
an indicator which denotes said cleavage direction of said semiconductor substrate.

18. The semiconductor chip as claimed in claim 17, wherein said semiconductor substrate includes a rectangular shape having four sides, a direction of said four sides differing from said cleavage direction.

19. The semiconductor chip as claimed in claim 17, further comprising an interconnect pattern having a wiring level which is same as a level of said indicator.

20. The semiconductor chip as claimed in claim 18, wherein said indicator is formed at each of sides of opposing sides of said four sides.
